(19) United States
(12) Patent Application Publication
(10) Pub. No.: US 2002/0146647 A1
(43) Pub. Date: Oct. 10, 2002

(54) Composition of photoresist remover effective against etching residue without damage to corrodible metal layer and process using the same

(75) Inventors: Hidemitsu Aoki, Tokyo (JP); Kenichi Nakabeppu, Tokyo (JP); Masahito Tanabe, Ishikawa (JP); Kazumasa Wakiya, Kanagawa (JP); Masakazu Kobayashi, Kanagawa (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION, TOKYO OHKA KOGYO CO., LTD.

(21) Appl. No.: 10/093,395

(22) Filed: Mar. 11, 2002

Related U.S. Application Data
(63) Continuation of application No. 09/655,838, filed on Sep. 6, 2000.

(30) Foreign Application Priority Data
Sep. 10, 1999 (JP) 11-257615

(51) Int. Cl. G03F 7/32

(52) U.S. Cl. 430/313; 430/331; 430/311

(57) ABSTRACT

A photo-resist mask is ashed after the pattern transfer, and is, thereafter, treated with liquid photo-resist remover, wherein photo-resist remover comprises salt produced through interaction between hydrofluoric acid and a base without metal ion, water, water soluble organic solvent and a derivative of benztriazole expressed by the general formula:

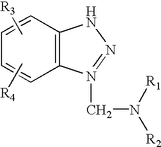

where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3, although the salt is powerful to etching residue, it is corrosive: However, the derivative of benztriazole exhibits good anti-corrosive property, and prevents a copper layer from the salt.

### FIELD OF THE INVENTION

This invention relates to patterning technologies and, more particularly, to a composition of photo-resist remover used in photolithography and a process for fabricating a semiconductor device.

### DESCRIPTION OF THE RELATED ART

The photolithography is popular in semiconductor fabrication technologies. As well known to a person skilled in the art, the photolithography proceeds as follows. Firstly, liquid resist is spread over an objective layer such as, for example, a semiconductor wafer, and is baked to form a photo-resist layer. A pattern image is transferred from a photo-mask to the photo-resist layer, and a latent image is formed in the photo-resist layer. The latent image is developed, and the photo-resist layer is formed into a photo-resist mask. Using the photo-resist mask, a part of the objective layer is, by way of example, etched away through a dry etching technique. Thus, the pattern image is finally transferred to the objective layer.

After the pattern transfer, the photo-resist mask is stripped off. The photo-resist mask is ashed in plasma, and the patterned objective layer is cleaned in liquid photo-resist remover. Various kinds of photo-resist remover have been developed. The compositions of the photo-resist remover are categorized in the organic sulfonic acid system, the organoamine system and the hydrofluoric acid system. The photo-resist remover in the organosulfonic acid system contains alkylbenzenesulfonic acid as the major component, and the photo-resist remover in the organioamine system contains organoamine such as, for example, hydrofluoric acid as the major component. The photo-resist remover in the hydrofluoric acid system contains hydrofluoric acid as the major component. It is proposed to mix anticorrosive compound such as saccharide or aromatic hydroxy compound in the photo-resist remover in the hydrofluoric acid system.

The patterns to be transferred have been miniaturized. A large number of circuit components are integrated on a semiconductor chip through the miniaturization, and the miniaturization is conducive to high-speed signal processing. Research and development efforts are being made for the fabrication process, and result in new process sequences. Although the photolithography is employed in the new process sequences, several steps are to be carried out under severe conditions, and other steps are expected to strictly achieve what the manufacturer designed. Accordingly, a new property is required for the photo-resist remover.

For example, low-resistive material such as copper is used in the new processes for the conductive pattern incorporated in the semiconductor integrated circuit device. The low-resistive conductive pattern prevents electric signals from undesirable delay. However, while a copper layer is being patterned into copper strips, etching residue, which was not produced in the conventional patterning process, is produced on the resultant structure, and the photo-resist remover is expected to clean the resultant structure. Moreover, copper is more corrodible rather than aluminum, and the photo-resist remover is expected to be less corrosive against the copper.

A typical example of the patterning process for copper stripes is described hereinbelow with reference to FIGS. 1A to 1C. The prior art process starts with preparation of a semiconductor substrate (not shown). Silicon oxide is deposited over the major surface of the semiconductor wafer, and forms a silicon oxide layer 1. Silicon nitride is deposited over the silicon oxide layer 1, and a silicon nitride layer 2 is laminated on the silicon oxide layer 1. Silicon oxide is deposited over the silicon nitride layer 2, again, and the silicon nitride layer 2 is overlain by a silicon oxide layer 3.

A groove is formed in the silicon oxide layer 3. The groove is filled with copper through well-known techniques, and a buried copper strip 20. Thus, the buried copper strip 20 extends in the silicon oxide layer 3.

Silicon nitride is deposited over the entire surface of the resultant structure, and forms a silicon nitride layer 6. Silicon oxide is deposited over the silicon nitride layer 6, and a silicon oxide layer 21 is laminated on the silicon nitride layer 6.

Liquid chemically amplified resist is spread over the entire surface of the silicon oxide layer 21, and a pattern image for a via-hole is transferred from a photo mask (not shown) to the chemically amplified resist layer for producing a latent image. The latent image is developed, and the chemically amplified resist layer is patterned into a photo-resist etching mask 22 as shown in FIG. 1A.

Using the photo-resist etching mask 22, the silicon oxide layer 21 is partially removed by using a dry etching technique until the silicon nitride layer 6 is exposed. The etchant has selectivity between the silicon oxide and the silicon nitride so that the etching rate to the silicon oxide is larger than the silicon nitride. The silicon nitride layer 6 is expected to serve as an etching stopper. A via hole is formed in the silicon oxide layer 21 through the dry etching, and is of the order of 0.2 micron in diameter. Etching residue 24 is produced from the chemically amplified resist during the dry etching, and is left on the inner surface of the photo-resist etching mask 22 as shown in FIG. 1B.

The silicon nitride etching stopper 6 is liable to be etched, and hardly defines an end point of the dry etching. The problem is reasoned as follows. In general, the loading effect influences the etching rate. When a micro via hole is formed through the etching, the loading effect is serious, and the etching is decelerated with time. The manufacturer takes the loading effect into account, and prolongs the etching time. This results in an over-etching, and the buried copper strip 20 tends to be exposed to the via-hole. If the buried copper stripe is dished, the silicon nitride layer 6 is partially made thin around the depression, and the thin silicon nitride layer is liable to be etched. This phenomenon is serious when the via-hole has a large aspect ratio. If the buried copper layer 20 and the silicon oxide layer 3 are covered with a silicon nitride layer thicker than the silicon nitride layer 6, the thick silicon nitride layer is left on the buried copper layer 20 against the over etching, and, accordingly, the buried copper layer 20 is less liable to be exposed. However, the thick silicon nitride layer gives rise to increase of the parasitic capacitance between adjacent buried copper layers, and the large parasitic capacitance is causative of signal delay. For this reason, the thick silicon nitride layer is not employable.

Upon completion of the via-hole, the photo-resist etching mask 22 is ashed in oxygen plasma, and the resultant structure is cleaned in the photo-resist remover. Namely, the photo-resist etching mask 22 is stripped off.

Subsequently, the buried copper layer 20 is exposed to the via-hole. In detail, the etching gas is changed to the composition appropriate for the silicon nitride, and the silicon nitride layer 6 is partially etched away. The silicon oxide layer 21 serves as an etching mask, and the silicon nitride layer 6 is removed from the upper surface of the buried copper layer 20. This results in that the buried copper layer 20 is exposed to the via-hole.

Subsequently, titanium is deposited over the entire surface of the resultant structure, and a titanium layer conformably extends over the entire surface. Titanium nitride is deposited over the titanium layer, and a titanium nitride layer is conformably laminated on the titanium layer. The titanium layer and the titanium nitride layer form a barrier-metal layer 26. The barrier-metal layer defines a recess in the via-hole. Tungsten is deposited over the entire surface. The tungsten fills the recess, and swells into a tungsten layer. The tungsten layer and the barrier-metal layer 27 are chemically mechanically polished until the silicon oxide layer 21 is exposed, again. A tungsten plug 27 is left in the recess as shown in FIG. 1C.

A problem is encountered in the prior art process described hereinbefore in that the photo-resist remover is less effective against the etching residue 24. In detail, while the silicon oxide layer 21 is being etched in the gaseous etchant, the etching residue 24 is deposited on the inner surface of the photo-resist etching mask 22 through the chemical reaction between the etchant and the materials forming parts of the semiconductor structure. The etching residue 24 contains the reaction products between the etchant and silicon nitride/copper. The etching residue 24 is not desirable for the formation of the barrier metal layer/contact plug 26/27. The photo-resist remover is expected to perfectly remove the etching residue from the resultant structure. However, the prior art photo-resist remover is less effective against the etching residue 24. The etching residue 24 is liable to be left on the silicon oxide layer 21 as shown in FIG. 2. Although the ashed photo-resist is removed from the upper surface of the silicon oxide 21, the etching residue 24 is strongly adhered to the silicon oxide layer 21, and stands on the silicon oxide layer 21. If the titanium and titanium nitride are deposited without removal of the etching residue 24, the etching residue 24 does not permit the deposition step to perfectly cover the entire surface with the titanium layer/titanium nitride layer. While the titanium and the titanium nitride are being deposited, the etching residue 24 may be broken into fragments. The fragments are buried in the tungsten, and the tungsten does not perfectly fill the recess. Thus, the etching residue 24 is an origin of defective contact.

On the other hand, if powerful photo-resist remover is used for the ashed photo-resist, the etching residue 24 is separated from the silicon oxide layer 21, and removed from the semiconductor structure. However, the powerful photo-resist remover is corrosive. Although the corrosion is ignoreable in aluminum layers, copper seriously suffers corrosion. The buried copper layer 20 is partially corroded, and a piece of rust 28 occupies an upper portion of the buried copper layer 20 as shown in FIG. 3.

Copper layers get thinner and thinner in semiconductor integrated circuit devices. The piece of rust 28 gives rise to increase of the resistance at the contact between the tungsten plug 27 and the buried copper layer 20. The piece of rust 28 makes the barrier metal layer 27 peel from the buried copper layer 20. Thus, the prior art powerful photo-resist remover is undesirable from the viewpoint of the reliability.

As described hereinbefore, anticorrosive compound such as benztriazole is mixed in the prior art photo-resist remover. The anticorrosive property of the known compound is variable together with temperature, and is less reliable. This means that a temperature controlling system is required for the anticorrosive compound containing photo-resist remover. The semiconductor manufacturer usually soaks plural semiconductor wafers in the liquid photo-resist remover after the ashing, and keeps the plural semiconductor wafers in the liquid photo-resist remover for a certain time. The liquid photo-resist remover is reserved in a vessel. If a temperature controlling system is prepared for the vessel, the cleaning system is enlarged, and the cost price is increased. In order to keep the cleaning system small and economical, the cleaning system is not equipped with any temperature controlling system, and the liquid photo-resist remover is varied in temperature together with the environment.

Although the clean room is controlled around 23 degrees in centigrade, it is difficult to strictly keep the room temperature constant over the clean room, because other systems and apparatus locally vary the room temperature. Another system may have a heat source, and a chiller may be installed in the same clean room. The heat source locally increases the room temperature, and the chiller cools the air therearound. Even so, the air conditioning system keeps the average room temperature in a relatively narrow range between 23 degrees and 25 degrees in centigrade. However, the local temperature around the heat source may exceed over 30 degrees in centigrade. Thus, the environment influences the temperature of the liquid photo-resist remover in the vessel, and, accordingly, the anticorrosion property is not guaranteed. Moreover, the liquid photo-resist remover is not constant in temperature in the vessel. In other words, the temperature is dispersed in the liquid photo-resist remover reserved in the vessel, and the anticorrosive compound acts at different temperature depending upon position of the semiconductor wafers in the vessel. In this situation, the anticorrosive compound is not reliable, and certain buried copper layers 20 are corroded in the powerful photo-resist remover. Thus, the prior art powerful photo-resist remover is not recommendable for a semiconductor structure with exposed copper layer. This means the above-described problem is left unsolved.

Another problem inherent in the prior art photo-resist remover is contamination. After the photo-resist etching mask is stripped off, the resultant structure is rinsed in pure water. However, residual contaminant is observed on the resultant structure. The contaminant is an ingredient of the photo-resist remover and the reaction product produced through the chemical reaction between the photo-resist and the photo-resist remover. The contaminant is an origin of defective products such as separation between layers.

### SUMMARY OF THE INVENTION

It is therefore an important object of the present invention to provide a photo-resist remover, which is effective against the etching residue without damage to a corrodible metallic layer as well as being less contaminative.

It is also an important object of the present invention to provide a pattern transfer process, in which the photo-resist remover is used.

In accordance with one aspect of the present invention, there is provided a composition of liquid photo-resist remover comprising a salt produced by interaction between at least one base without metal ion and hydrofluoric acid, water soluble organic solvent, water and a derivative of benztriazole expressed by the general formula:

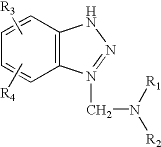

where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3.

In accordance with another aspect of the present invention, there is provided a process for fabricating a semiconductor device, comprising the steps of.

a) preparing a laminated structure having a corrodible layer and at least one target layer;

b) forming a photo-resist mask on said laminated structure for defining an area in said at least one target layer;

c) carrying out a predetermined treatment on said area so that said corrodible layer is exposed; and

d) removing said photo-resist mask by using a photo-resist remover comprising salt produced by interaction between at least one base without metal ion and hydrofluoric acid, water soluble organic solvent, water and a derivative of benztriazole expressed by the general formula

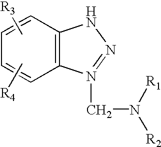

where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3.

### BRIEF DESCRIPTION OF THE DRAWINGS

The features and advantages of the composition of photo-resist remover and the process for fabricating a semiconductor device will be more clearly understood from the following description taken in conjunction with the accompanying drawings in which:

FIGS. 1A to 1C are cross sectional views showing the prior art process for forming the contact plug;

FIG. 2 is a cross sectional view showing the etching residue left when the photo-resist etching mask is stripped off;

FIG. 3 is a cross sectional view showing the buried copper layer partially corroded due to the etching residue;

FIGS. 4A to 4H are cross sectional views showing a pattern transfer process according to the present invention;

FIG. 5A is a perspective view showing etching residue formed along a groove; and

FIG. 5B is a perspective view showing etching residue formed around a through-hole.

### DETAILED DESCRIPTION OF THE INVENTION

The photo-resist remover according to the present invention comprises at least four components, i.e., salt produced by interaction between at least one base without metal ion and hydrofluoric acid, water soluble organic solvent, water and a derivative of benztriazole. The derivative of benztriazole is expressed by the general formula

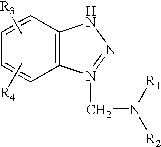

where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3.

Salt

The first component is the salt. Ammonium fluoride is the most preferable as the salt. Only one base without metal ion may react with hydrofluoric acid. Otherwise, two or more than two bases may react with hydrofluoric acid. The first component, i.e., the salt ranges from 0.2 percent by weight to 30 percent by weight. The highest limit of salt is preferably at 20 percent by weight, and the lowest limit of salt is preferably at 0.5 percent by weight. When the salt is fallen within the above range, the photo-resist remover according to the present invention effectively eliminates etching residue from a semiconductor structure together with ashed photo-resist, and less damages a corrodible metal layer such as, for example, a copper layer.

Organic amine, aqueous ammonia and lower-alkyl quaternary ammonium base do not contain any metal ion, and are used as the base without metal ion. Examples of the organic amine are hydroxyamines, primary aliphatic amine, secondary aliphatic amine, tertiary aliphatic amine, alicyclic amine, aromatic amine and heterocyclic amine.

The hydroxyamines are, by way of example, hydroxylamine expressed by the chemical formula of NH₂OH, N-methylhydroxylamine, N, N-dimethylhydroxylamine and N, N-diethylhydroxylamine.

Examples of the primary aliphatic amine are monoethanol amine, ethylenediamine and 2-(2-aminoethyl amino) ethanol. Examples of the secondary aliphatic amine are diethanolamine, dipropylamine and 2-etylaminoethanol. Examples of the tertiary aliphatic amine are dimethylaminoethanol and etyldiethanolamine.

Examples of the alicyclic amine are cyclohexylamine and dicyclohexylamine. Examples of the aromatic amine are benzylamine, dizenzylamine and N-methylbenzylamine.

Examples of heterocyclic amine are pyrrole, pyrrolidine, pyrrolidone, pyridine, morpho line, biradine, piperidine, N-hydroxyethylpiperidine, oxazole and thiazole.

Examples of the lower-alkyl quaternary ammonium base are tetraethylammoniumhydroxide abbreviated as TMAH, tetraethylammoniumhydroxide, tetrapropylammoniumhydroxide, trimethylethylammoniumhydroxide, (2-hydroxyethyl) trimethylammoniumhydroxide, (2-hydroxyethyl) triethylammoniumhydroxide, (2-hydroxyethyl) tripropylammo niumhydroxide and (1-hydroxypropyl) trimethylammoniumhydroxide.

Aqueous ammonia, monoethanolamine, tetramethylammoniumhydroxide and (2-hydroxyethyl) trimethylammoniumhydroxide are easily obtainable and superior in safety. For this reason, these compounds are preferable for the photo-resist remover according to the present invention.

The salt is produced as follows. Firstly, at least one base without metalion is selected from the above-described candidates, and hydrofluoric acid is prepared. The hydrofluoric acid is 50 to 60 percent solution of hydrogen fluoride, which is commercially obtainable in the market. The salt is dissolved in the hydrofluoric acid, and pH is regulated to 5-8.

Water Soluble Organic Solvent

The second component is the water soluble organic solvent. The organic solvent used for the photo-resist remover is to be well mixed with the water and the other components. The water soluble organic solvent is to be fallen within the range from 30 percent to 80 percent by weight from the viewpoint of the peeling and the damage to the corrodible metal layer. When the water soluble organic solvent is regulated to 40 percent to 70 percent by weight, the anti-corrosive property is well balanced with the peeling characteristics.

Examples of the water soluble organic solvent are sulfoxides, sulfones, amides, lactams, imidazolidinones, lactones, polyhydric alcohols and derivatives thereof. One of the above-described organic compounds may serve as the water soluble organic solvent. More than one organic compound may be mixed for the water soluble organic solvent.

An example of the sulfoxides is dimethylsulfoxide.

Examples of the sulfones are dimethylsulfone, diethylsulfone, bis(2-hydroxyethyl) sulfone and tetramethylenesulfone.

Examples of the amides are N-dimethylformamide, N-methylformamide, N, N-dimethylacetamide, N-methylacetamide and N, N-diethylacetamide.

Examples of the lactams are N-methyl-2-pyrrolidone, N-ethyl-2-pyrrollidone, N-propyl-2-pyrrolidone, N-hydroxymethyl-2-prrollidone and N-hydroxyethyl-2-pyrrolidone.

Examples of the imidazolidinones are 1,3-dimethyl-2-imidazolidinone, 1,3-diethyl-2-imidazolidinone and 1,3-diisopropyl-2-imidazolidinone.

Examples of the lactones are γ-butyrolactone and δ-valerolacione.

Examples of the polyhydric alcohols are ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether and diethylene glycol monobutyl ether.

Dimethylsulfoxide, N, N-dimethylformamide, N, N-dimethylacetamide, N-methyl-2-pyrrolidone, 1,3-dimethyl-2-imidazolidinone, ethylene glycol and diethylene glycol monobutyl ether are preferable for the water soluble organic solvent from the viewpoint of peeling. Especially, dimethylsulfoxide is the most preferable, because the dimethylsulfoxide less damages the corrodible metal layer.

Water

The third component is water. Although the water soluble organic solvent per se contains water, the photo-resist remover according to the present invention further contains water. The water as the third component is to be fallen within the range from 10 percent to 50 percent by weight, because the water in the above range causes the first and second components to clearly exhibit the properties of the first and second components. When the third component is regulated to 20 percent to 40 percent by weight, the photo-resist remover according to the present invention exhibits good peeling characteristics and good anti-corrosive property.

Derivative of Benztriazole

The fourth component is a derivative of benztriazole. The derivative of benztriazole is expressed by the following general formula.

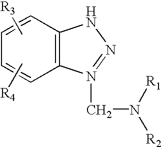

Each of R₁ and R₂ represents a hydroxyalkyl group having the carbon number between 1 and 3 or an alkoxyalkyl group having the carbon number between 1 and 3, and each of R₃ and R₄ represents a hydrogen atom or an alkyl group having the carbon number between 1 and 3. R₁ is either identical with or different from R₂. Similarly, R₃ is either identical with or different from R₄.

The derivative of benztriazole prevents corrodible metal such as copper from corrosive substance such as the salt serving as the first component, and, accordingly, exhibits good anti-corrosive property. The derivative of benztriazole is superior in anti-corrosive property to benzotriazole expressed as

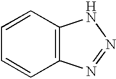

The derivative of benzotriazole exhibits good anti-corrosive property in wide temperature range, and only a little lust is left after the rinse in pure water. Thus, the derivative of benzotriazole is appropriate to the photo-resist remover.

Derivatives of benzotriazole are on the market. Chiba Specialty Chemicals Corporation commercially sells the derivative of benzotriazole, and the product name is IRGAMET series. Especially, IRGAMET 42 is preferable. IRGAMET 42 is (2,2′-[[methyl-1H-benztriazole-1-yl] methyl] imino) bisethanol), which is expressed as

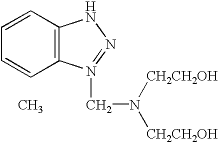

The fourth component, i.e., the derivative of benztriazole is to be fallen within the range from 0.1 percent to 10 percent by weight. When the derivative of benztriazole is regulated to 0.5 percent to 5 percent by weight, the photo-resist remover exhibits good anti-corrosive property.

The first component, i.e., the salt is effective against the etching residue. However, the salt is strongly corrosive. This means that the corrodible metal such as copper is damaged by the salt. The fourth component, i.e., the derivative of benztriazole prevents the corrodible metal from the salt, and eliminates the undesirable property from the salt. Thus, the combination between the salt and the derivative of benztriazole results in the photo-resist remover, which is effective against the etching residue without damage to the corrodible metal layer.

The salt, the water soluble organic solvent, the water and the derivative of benztriazole are essential components of the photo-resist remover according to the present invention. Another additive may be mixed with the four essential components.

The photo-resist remover according to the present invention is available for various kinds of photo-resist. An example is positive resist containing naphthoquinonedizido compound and novolak resin. Another example is positive resist containing photoacid generator, compound decomposed by photoacid and alkaline soluble resin. The photoacid generator generates the photoacid in exposure to light, and the compound is decomposed so as to increase the solubility to alkali solution. Yet another example is also positive resist containing the photoacid generator and alkali soluble resin. The alkali soluble resin has a group decomposed by the photoacid so as to increase the solubility to alkali solution. Still another example is negative resist, which contains the photoacid generator, cross linking agent and alkali soluble resin.

### DESCRIPTION OF THE PREFERRED EMBODIMENTS

The present inventors prepared several kinds of photo-resist remover, and investigated them as follows.

Elimination of Ashed Photo-resist and Etching Residue

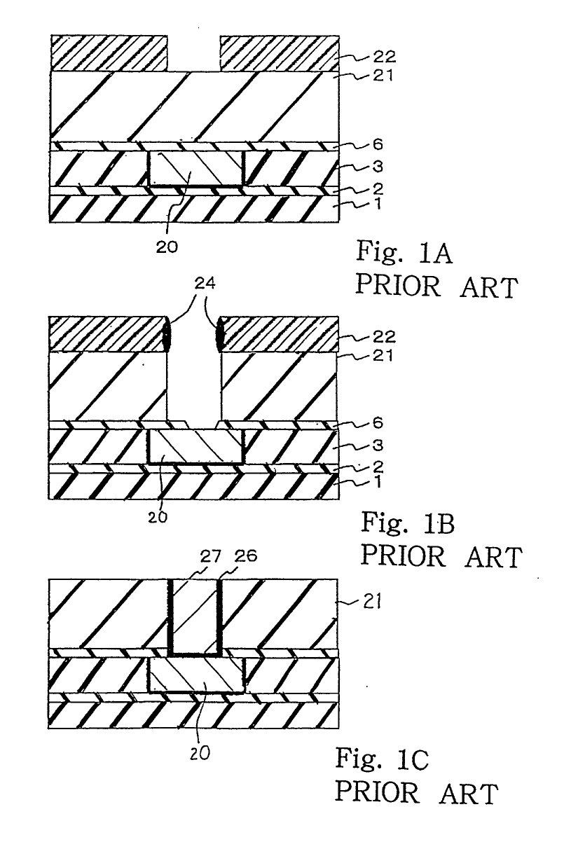

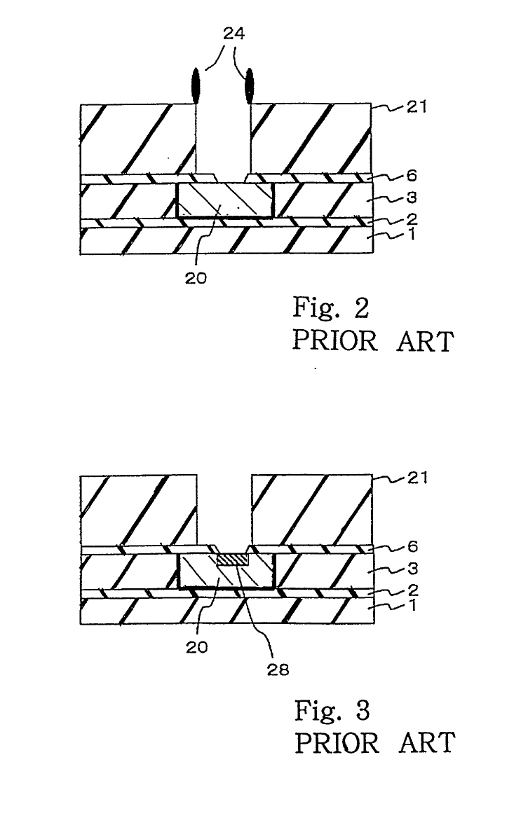

The present inventors firstly prepared the semiconductor structures shown in FIG. 1B through the process described hereinbefore. In detail, the silicon nitride layers 2 were deposited over the silicon wafers 1, and, thereafter, the silicon oxide layers 3 were laminated on the silicon nitride layers 2, respectively. The buried copper layers 20 were respectively formed in the silicon oxide layers 3, and silicon nitride layers 6 and the silicon oxide layers 31 were successively formed through the chemical vapor deposition. Positive photo-resist was spun onto the silicon oxide layers 21. The positive photo-resist was manufactured by Tokyo Ohka Kogyo Corporation Ltd., and was sold in the market as PEX4. The photo-resist layers were exposed to KrF light through a photo-mask (not shown), and a mask pattern was transferred from the photo-mask to the photo-resist layers. The latent images were developed in 2.38 weight percent tetramethylammoniumhydroxide solution. The photo-resist layers were patterned to the photo-resist etching masks 22 (see FIG. 1A). Using the photo-resist etching masks 22, the silicon oxide layers 21 were selectively etched, and the semiconductor structures shown in FIG. 1B were obtained.

Subsequently, the photo-resist etching masks 22 were ashed, and, thereafter, the ashed photo-resist and etching residue 24 were removed in the photo-resist remover Nos. 1, 2, 3, 4, 5, 6 and 7 at 23 degrees in centigrade for 10 minutes. The compositions of the photo-resist remover Nos. 1 to 6 were shown in table 1. In table 1, IRGAMET 42 was (2,2′-[[methyl-1H-benztriazole-1-yl] methyl] imino) bis-ethanol).

TABLE 1

| | No. 1 | No. 2 | No. 3 | No. 4 | No. 5 | No. 6 |
|---|---|---|---|---|---|---|
| Hydro- | 0.05 | 0.1 | — | 0.05 | 0.05 | 0.05 |
| fluoric | WT % | WT % | | WT % | WT % | WT % |
| Acid | | | | | | |
| Ammo- | 1 WT % | 1 WT % | 1 WT % | 1 WT % | 1 WT % | 1 WT % |
| nium | | | | | | |
| Fluoride | | | | | | |
| Water | 30 WT % | 30 WT % | 30 WT % | 30 WT % | 30 WT % | 30 WT % |
| Water | DMSO | NMP | DMSO | DMSO | DMSO | DMSO |
| Soluble | Remaining | Remaining | Remaining | Remaining | Remaining | Remaining |
| Organic | Part | Part | Part | Part | Part | Part |
| Solvent | | | | | | |
| Deriva- | IRGAME | IRGAME | IRGAME | Benztri- | 2,3- | — |
| tive of | T 42 | T 42 | T 42 | azole | hydroxy- | |
| Benztri- | 1 WT % | 1 WT % | 1 WT % | 1 WT % | propyl- | |
| azole | | | | | benztri- | |
| | | | | | azole | |
| | | | | | 1 WT % | |

In table 1, DMSO and NMP stand for dimethylsulfoxide and N-methyl-2-pyrolidone, respectively. Term “percent by weight” is abbreviated as “WT %”.

After the treatment with the photo-resist remover, the silicon wafers were rinsed in pure water. The present inventors observed the silicon wafers through a scanning electron microscope (not shown) to see whether or not the ashed photo-resist and the etching residue remained thereon. The present inventor confirmed that the ashed photo-resist and the etching residue did not remain on the silicon wafers.

Corrosion and Residual Contaminant

The present inventors prepared silicon wafers, the entire major surfaces of which were coated with copper layers. The silicon wafers coated with the copper layers were dipped in the photo-resist remover Nos. 1, 2, 3, 4, 5 and 6 at 23 degrees in centigrade for 10 minutes, and, thereafter, were rinsed in pure water. Thereafter, the present inventors observed the copper layers through the scanning electron microscope to see whether or not the copper layers were corroded and whether or not any contaminant was adhered to the copper layers. Observations were summarized in table 2.

TABLE 2

| Photo-resist Remover | Corrosion of Cu | Contaminant |
|---|---|---|
| No. 1 | A | A |
| No. 2 | A | A |
| No. 3 | A | A |
| No. 4 | B | A |
| No. 5 | A | B |
| No. 6 | B | A |

In the first column, the mark of “A” represented the observation that the copper layer was not corroded, and the mark of “B” represented the observation that the copper layer was corroded. In the second column, the mark of “A” represented the observation that there was not any contaminant after the rinse, and the mark of “B” represented the observation that the contaminant was found after the rinse.

The photo-resist remover according to the present invention did not corrode the corrodible metal. The pure copper layer was not corroded in the photo-resist remover. The photo-resist remover according to the present invention did not corrode copper alloy containing copper at equal to or more than 90 percent by weight. Aluminum-copper alloy was an example of the copper containing alloy.

Temperature Dependency

The present inventors prepared silicon wafers, and coated the entire surfaces of the silicon wafer with copper. The present inventors further prepared the photo-resist remover, the compositions of which were shown in table 3.

TABLE 3

| Photo-resist Remover | No. 7 | No. 8 | No. 9 |
|---|---|---|---|
| Hydrofluoric Acid | 0.05 WT % | 0.05 WT % | 0.05 WT % |
| Ammonium fluoride | 1 WT % | 1 WT % | 1 WT % |
| Water | 30 WT % | 30 WT % | 30 WT % |
| Water Soluble Organic | DMSO | DMSO | DMSO |
| Solvent | Remaining | Remaining | Remaining |
| | Part | Part | Part |
| Derivative of Benztriazole | IRGAME | Benztri- | — |
| | T 42 | azole | |
| | 1 WT % | 1 WT % | |

In table 3, “DMSO” represented dimethylsulfonide, and “WT %,” stood for the unit in percent by weight.

The photo-resist remover Nos. 7, 8 and 9 were separated into two parts, and maintained the first parts at 30 degrees in centigrade and the second parts at 40 degrees in centigrade. The present inventors dipped the silicon wafers into the first parts of the photo-resist remover Nos. 7, 8 and 9 for ten minutes and the other silicon wafers into the second parts of the photo-resist remover Nos. 7, 8 and 9 also for ten minutes. The silicon wafers were rinsed in pure water. After the rinse, the present inventors observed the silicon wafers through the scanning electron microscope to see whether or not the copper layers were corroded. The observations were summarized in table 4.

TABLE 4

| Photo-resist | 30 degrees in | 40 degrees in |
|---|---|---|
| Remover | centigrade | centigrade |
| No. 7 | A | A |
| No. 8 | B | C |
| No. 9 | C | C |

In table 4, the mark of “A” was indicative of the copper layer without any corrosion, the mark “B” represented that corrosion was observed, and the mark of “C” stood for the copper layer violently corroded.

Pattern Transfer through Photo-lithography

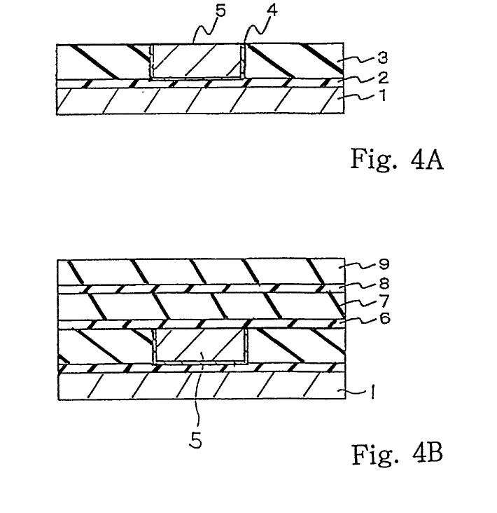

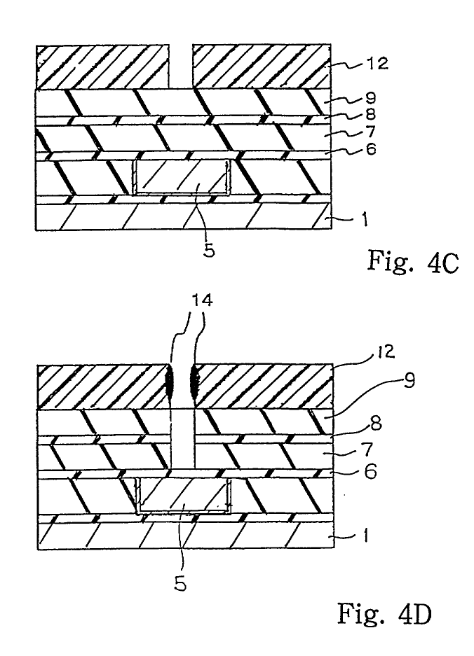

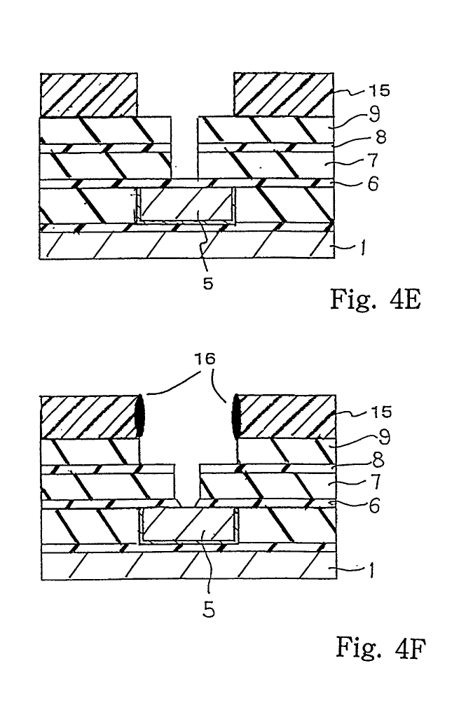

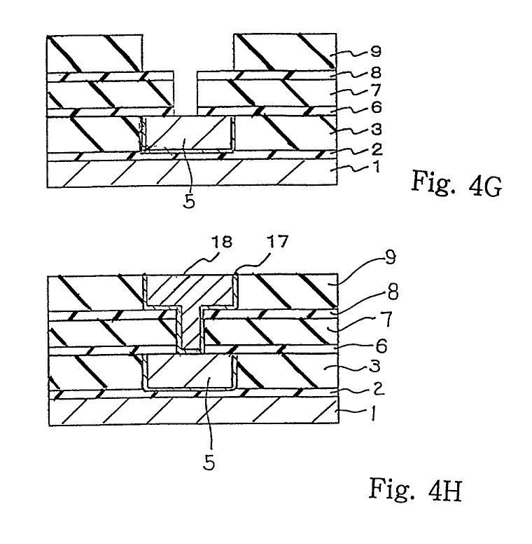

The photo-resist remover is available for a pattern transfer process. FIGS 4A to 4H show a process for transferring a pattern image to a semiconductor structure. The process starts with preparation of a silicon substrate 1. Circuit components of an integrated circuit may be formed on the silicon substrate 1. Silicon nitride is deposited over the major surface of the silicon substrate 1, and forms a silicon nitride layer 2. Silicon oxide is deposited over the entire surface of the silicon nitride layer 2, and a silicon oxide layer 3 is laminated on the silicon nitride layer 2. A photo-resist etching mask (not shown) is patterned on the silicon oxide layer 3, and the silicon oxide is selectively etched so as to form a groove in the silicon oxide layer 3. The photo-resist etching mask is stripped off.

Tantalum is deposited over the entire surface, and a tantalum layer 4 is conformably formed so as to define a secondary groove. Copper is grown on the tantalum layer through an electro-plating technique, and forms a copper layer. The copper layer and the tantalum layer are chemically mechanically polished until the silicon oxide layer 3 is exposed. A tantalum layer 4 and a copper layer 5 are left in the groove, and form in combination a lower buried conductive layer in the groove as shown in FIG. 4A.

Subsequently, silicon nitride is deposited over the entire surface of the structure, and forms a silicon nitride layer 6. Silicon oxide is deposited over the silicon nitride layer 6, and a silicon oxide layer 7 is laminated on the silicon nitride layer 6. Silicon nitride is deposited over the silicon oxide layer 7, again, and the silicon oxide layer 7 is overlain by a silicon nitride layer 8. Silicon oxide is deposited over the silicon nitride layer 8, again, and a silicon oxide layer 9 is formed on the silicon nitride layer 8. The resultant structure is shown in FIG. 4B.

Positive photo-resist is spun onto the silicon oxide layer 9. The positive photo-resist is PEX4 manufactured by Tokyo Ohka Kogyo Corporation ltd. A pattern image is transferred through KrF light to the photo-resist layer, and the latent image is developed. A photo-resist etching mask 12 is patterned on the silicon oxide layer 9. The photo-resist etching mask 12 has an opening over the copper layer 5 as shown in FIG. 4C.

Using the photo-resist etching mask, the silicon oxide layer 9, the silicon nitride layer 8 and the silicon oxide layer 7 are partially etched by using a dry etching. The etching gas has selectively to the silicon oxide larger than that to the silicon nitride. A through-hole is formed in the silicon oxide/silicon nitride layers 9/8/7, and is 0.2 micron in diameter. The silicon nitride layer 6 is exposed to the through-hole, and etching residue 14 is produced on the inner surface of the photo-resist etching mask 12 as shown in FIG. 4D. The photo-resist etching mask 12 is stripped off.

A photo-resist etching mask 15 is patterned through the photo-lithography on the silicon oxide layer 9. The photo-resist etching mask 15 is formed from the positive photo-resist PEX4. The photo-resist etching mask 15 has a groove wider than the opening of the photo-resist etching mask 12. The through-hole is exposed to the groove, and the silicon oxide layer 9 around the through-hole is also exposed to the opening of the photo-resist etching mask 15 as shown in FIG. 4E.

The silicon oxide layer 9 is partially etched by using the dry etching. A groove is formed in the silicon oxide layer 9, and etching residue 16 is produced on the inner surface of the photo-resist etching mask 15 as shown in FIG. 4F. The silicon nitride layer 6 may be unintentionally etched during the over etching so that a part of the copper layer 5 is exposed to the through-hole.

Subsequently, the photo-resist etching mask 15 is stripped off as follows. Firstly, the photo-resist etching mask 15 is ashed in oxygen plasma. The ashed photo-resist is removed from the silicon oxide layer 9. The liquid photo-resist remover No. 1 is used, and the ashed photo-resist is treated with the liquid photo-resist remover at 23 degrees in centigrade for 10 minutes. The resultant semiconductor structure is rinsed in pure water.

The silicon nitride layer 6 exposed to the through-hole is etched away. Then, the copper layer 5 is exposed to the through-hole as shown in FIG. 4G. A tantalum layer 17 and a copper layer 18 are formed in the through-hole and the groove as similar to the tantalum layer 4 and the copper layer 5, and form an upper buried conductive line as shown in FIG. 4H.

The present inventors fabricated samples of the semiconductor structure through the process described hereinbefore. The present inventors observed the appearance of the samples and the cutting planes of the samples shown in FIG. 4G through the scanning electron microscope. The present inventor confirmed that any etching residue was perfectly removed from the silicon oxide layer 9. The present inventors further confirmed that the copper layer 5 was not corroded. After the rinse, any contaminant was not left on the samples.

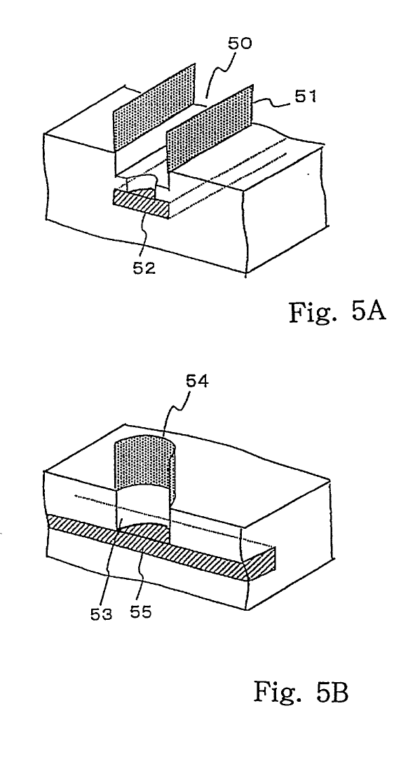

The investigation was carried out after the completion of the groove, i.e., the through-hole had been already formed under the groove. The etching residue 16 extended along the both sides of the groove as similar to etching residue 51 on both sides of a groove 50 formed over a lower buried conductive line 52 shown in FIG. 5A. On the other hand, the etching residue 14 was formed around the through-hole as similar to etching residue 54 around a through-hole 53 for a lower buried conductive line 55 shown in FIG. 5B. The etching residue 16 was much more than the etching residue 14. For this reason, the removal of the etching residue 16 was more difficult than the removal of the etching residue 14. Moreover, the copper layer 5 was exposed to the photo-resist remover twice, i.e., the removal of the ashed photo-resist etching mask 12 and the removal of the ashed photo-resist etching mask 15. This meant that the copper layer 5 was much liable to be damaged. Although the present inventors observed the copper layer 5 after the formation of the groove in the silicon oxide layer 9, any etching residue was left on the silicon oxide layer 9, and the copper layer 5 was not corroded. Thus, the photo-resist remover according to the present invention was improved in the anti-corrosion property and in the peeling characteristics.

As will be appreciated from the foregoing description, the photo-resist remover according to the present invention is powerful on the etching residue without damage to the corrodible metal. The temperature is not influential on the anti-corrosive property of the photo-resist remover according to the present invention. Any contaminant is left after the rinse in pure water.

Moreover, the photo-resist remover according to the present invention is conducive to the acceleration of signal propagation. Even if a corrodible metal is exposed through an opening, the photo-resist remover does not corrode the metal. This means that the manufacturer can reduce the thickness of the silicon nitride layers. The silicon nitride layers prevent active regions in the silicon layers from copper, and are indispensable. If a parasitic capacitance is dominated by the silicon nitride layer, the signal is delayed due to the large parasitic capacitance. However, when the silicon nitride layer is reduced in thickness, the parasitic capacitance is dominated by silicon oxide layers, and is decreased. This results in the acceleration of the signal propagation.

Finally, any temperature controlling system is not required for a cleaning apparatus by virtue of the stability of the peeling characteristics of the photo-resist remover according to the present invention. Thus, the photo-resist remover according to the present invention is conducive to the reduction of the installation cost of the semiconductor manufacturing system. The manufacturer freely layouts the semiconductor manufacturing apparatus in the clean room, because the photo-resist remover according to the present invention is available in any temperature environment.

Although particular embodiments of the present invention have been shown and described, it will be apparent to those skilled in the art that various changes and modifications may be made without departing from the spirit and scope of the present invention.

For example, the photo-resist remover according to the present invention may be used to remove a photo-resist ion-implantation mask.

What is claimed is:

1. A composition of liquid photo-resist remover comprising salt produced by interaction between at least one base without metal ion and hydrofluoric acid, water soluble organic solvent, water and a derivative of benztriazole expressed by the general formula: 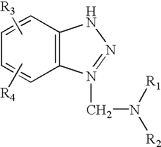
where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3.

2. The composition of liquid photo-resist remover as set forth in claim 1, in which said salt, said water soluble organic solvent, said water and said derivative of benztriazole are respectively fallen within the range between 0.2 percent and 30 percent by weight, the range between 30 percent and 80 percent by weight, the range between 10 percent and 50 percent by weight and the range between 0.1 percent and 10 percent by weight.

3. The composition of liquid photo-resist remover as set forth in claim 1, in which said at least one base is selected from the group consisting of organic amine, aqueous ammonia and sub-alkyl quaternary ammonium base.

4. The composition of liquid photo-resist remover as set forth in claim 3, in which said organic amine is selected from the group consisting of hydroxyamines, primary aliphatic amine, secondary aliphatic amine, tertiary aliphatic amine, alicyclic amine, aromatic amine and heterocyclic amine.

5. The composition of liquid photo-resist remover as set forth in claim 1, in which said water soluble organic solvent is selected from the group consisting of sulfoxides, sulfones, amides, lactams, imidazolidinones, lactones, polyhydric alcohols and derivatives thereof.

6. The composition of liquid photo-resist remover as set forth in claim 1, in which said derivative of benztriazole is (2,2′-[[methyl-2H-benztriazole-1-yl] methyl] imino) bis-ethanol) expressed as

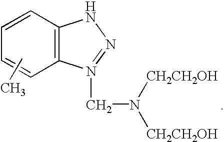

7. The composition of liquid photo-resist remover as set forth in claim 1, in which said at least one base and said water soluble organic solvent are selected from the group consisting of aqueous ammonia, monoethanolamine, tetramethylammoniumhydroxide and (2-hydroxyethyl) trimethylammoniumhydroxyd and the group consisting of dimethylsulfoxide, N, N-dimethylformamide, N, N-dimethylacetamide, N-methyl-2-pyrrolidone, 1,3-dimethyl-2-imidazolidinone, ethylene glycol and diethylene glycol monobutyl ether, respectively, and said derivative of benztriazole is (2,2′-[[methyl-1H-benztriazole-1-yl] methyl] imino) bis-ethanol).

8. The composition of liquid photo-resist remover as set forth in claim 1, in which said salt, said water soluble organic solvent and said derivative of benztriazole are ammonium fluoride, dimethylsulfoxide and (2,2′-[[methyl-1H-benztriazole-1-yl] methyl] imino) bis-ethanol), respectively.

9. A process for fabricating a semiconductor device, comprising the steps of:
a) preparing a laminated structure having a corrodible layer and at least one target layer;
b) forming a photo-resist mask on said laminated structure for defining an area in said at least one target layer;
c) carrying out a predetermined treatment on said area so that said corrodible layer is exposed; and
d) removing said photo-resist mask by using a photo-resist remover comprising salt produced by interaction between at least one base without metal ion and hydrofluoric acid, water soluble organic solvent, water and a derivative of benztriazole expressed by the general formula 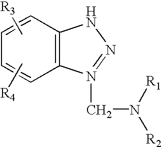
where each of R₁ and R₂ represents a hydroxyalkyl group having the carbon number between 1 and 3 or an alkoxyalkyl group having the carbon number between 1 and 3 and each of R₃ and R₄ represents a hydrogen atom or an alkyl group having the carbon number between 1 and 3.

10. The process as set forth in claim 9, in which said corrodible layer is formed of copper.

11. The process as set forth in claim 9, in which said corrodible layer is formed of copper alloy containing copper at least 90 percent by weight.

12. The process as set forth in claim 9, in which said predetermined treatment is an etching.

13. The process as set forth in claim 9, in which said step d) includes the sub-steps of
d-1) ashing said photo-resist mask, and
d-2) removing the ashed photo-resist by applying said photo-resist remover.
